(19) United States
(12) Patent Application Publication
(10) Pub. No.: US 2009/0244836 A1
(43) Pub. Date: Oct. 1, 2009

(54) Attach a Mobile Mouse to Your Laptop

(76) Inventors: Tung-Lin Leng, Macroon Co. Cork (IE); Padraig McLoughlin, Killygoan Co. Monagham (IE); Denis O'Keefe, Newmarket Co. Cork (IE)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/059,929

(22) Filed: Mar. 31, 2008

(51) Int. Cl. G06F 1/16; H05K 7/14

(52) U.S. Cl. 361/679.58

(57) ABSTRACT

A docking system which can be used with any laptop, and can allow a mouse or other peripheral device to attach to the back surface of the laptop screen, such as the top of the display when closed. A docking piece is attached to the flat surface of the laptop by means of an adhesive or other mechanism. The mouse or other accessory includes a docking element which engages the docking piece with a restraining force applied. A flat tool to remove the docking piece when it is no longer desired to be used.

### BACKGROUND OF THE INVENTION

The present invention relates to mechanisms for attaching a mouse to a laptop computer.

A number of patents describe mechanisms for attaching a mouse to a laptop. Most require a special recess or other structure on the laptop. Primax Published application 20070132731 shows a mouse with a hook that attaches to a hole in a laptop. HP U.S. Pat. No. 6,970,156 shows a mouse which collapses and fits in a PCMCIA slot (similar designs are shown in U.S. Pat. No. 7,233,319 and Published application no. 20060176277). U.S. Pat. No. 5,409,107 shows a holder for a mouse which attaches to the side of a computer CRT display.

A number of patents show rectangular mice that fit in rectangular slots of a laptop. Such designs are shown, for example, in U.S. Pat. No. 6,163,326, U.S. Pat. No. 7,330,923. U.S. Pat. No. 6,392,634 shows a trackball module on a laptop which can be removed and used as a mouse. U.S. Pat. No. 6,784,870 shows a rounded mouse which attaches to a special curved recess at the front of a laptop.

There are products in the market that provide adhesive mouse holders that can be attached to a surface, such as the vertical side of a computer monitor. Examples are the Ergotron mouse holder and the Compucessory mouse holder.

It would be desirable to have a mechanism for attaching a mouse to any computer in a simple manner. Often, a user needs to move around, and doesn't want to place the mouse in a briefcase, backpack, etc. when moving a short distance, such as to another room in the home or another office in a building.

### BRIEF SUMMARY OF THE INVENTION

The present invention provides a docking system which can be used with any laptop, and can allow a mouse or other peripheral device to attach to the back surface of the laptop screen, such as the top of the display when closed. A docking piece is attached to the back surface of the laptop screen by means of an adhesive or other mechanism. The mouse or other accessory includes a docking element which engages the docking piece with a restraining force applied.

In one embodiment, a mushroom shaped docking piece is provided for attaching to the back surface of the laptop screen by a removable adhesive. The mouse or other peripheral includes a slot which engages under the mushroom head of the docking piece. Spring loaded clamps in the slot are pushed outward as the mouse is docked, providing the clamping force. The clamp partially closes around the mushroom head as the mouse is completely engaged, snapping it into place. The amount of force holds it securely, while allowing the user to easily remove the mouse.

In one embodiment, an ON/OFF switch is provided on the bottom of the mouse (or other peripheral) in the area of the slot. When the mouse engages the docking piece, the mushroom head presses on the switch, turning off power to the mouse when it is docked. When the mouse is released, the pressure on the switch is removed, and the mouse is turned back on. Rather than a mechanical switch, alternate embodiments use a proximity detection switch (capacitance), optical switch, or magnetic switch.

Other embodiments of the invention use a similar docking piece with different clamping systems on the accessory. For example, one uses a metal wire to lock onto the docking piece. Another uses a sheet metal clamp. Another uses a rubber fixture on the accessory, with the rubber compressing to provide the clamping force. Other embodiments use different shapes for the docking piece. One uses a clamping piece with a groove that a complementary rail on the accessory slides into. A groove or slot may be combined with a clip that goes over the edge of the laptop screen, like a webcam clip.

Other embodiments use a docking piece with a magnet, or a magnet in the accessory that interacts with metal in the docking piece. The docking piece is attached in a different manner in different embodiments. In one embodiment, it has a hook or clamp which goes around the edge of the display, and is secured by sandwich action when the laptop is closed. In another embodiment it hooks to a piece which engages the USB port or other ports of the laptop.

In one embodiment, the docking piece uses an adhesive-type structure to hold the mouse. For example, a reusable adhesive, such as a strong Post-It® or flypaper type adhesive can be used. Alternately, a suction cup or array of small suction cups is used. Another embodiment uses synthetic Gecko hair for dry adhesion. Another embodiment uses a Velcro® type fastener. In all these embodiments, the same adhesive structure can be used to attach the docking piece to the laptop, and to attach the accessory to the laptop, or different combinations could be used.

### BRIEF DESCRIPTION OF THE DRAWINGS

FIG. 1 is a diagram of a docking piece according to an embodiment of the invention.

FIG. 2 is a diagram of a docking element on a mouse or other accessory according to an embodiment of the invention.

FIGS. 3A and 3B show a top and bottom view of one embodiment of a tool for removing the docking piece.

FIGS. 4A and 4B illustrate the use of the tool of FIGS. 3a and 3B to remove a docking piece from a back surface of a laptop screen according to one embodiment of the invention.

FIG. 5 is a diagram illustrating the docking element of FIG. 2 on the bottom of a mouse with an on/off switch.

FIG. 6 is a diagram of a docking element using a wire lock according to an embodiment of the invention.

FIGS. 7 and 8 are diagrams of a docking element using vertical rotating clamps according to an embodiment of the invention.

FIG. 9 is a diagram of an embodiment using rubber pieces for clamps according to an embodiment of the invention.

FIG. 10 is a diagram of an embodiment with a docketing element as a press fit groove, with a metal ball for tactile feedback.

FIG. 11 is a diagram of an embodiment with magnetic and metal pieces used for the docking piece and docking element.

FIGS. 12 and 13 are diagrams of a clip-type docking piece according to an embodiment of the invention.

FIG. 14 is a diagram of a rotating clip mounted in the mouse according to an embodiment of the invention.

FIG. 15 is a diagram of an embodiment of a clamping element, where the clamp can slide of out the mouse.

### DETAILED DESCRIPTION OF THE INVENTION

Mushroom Head with Clamp

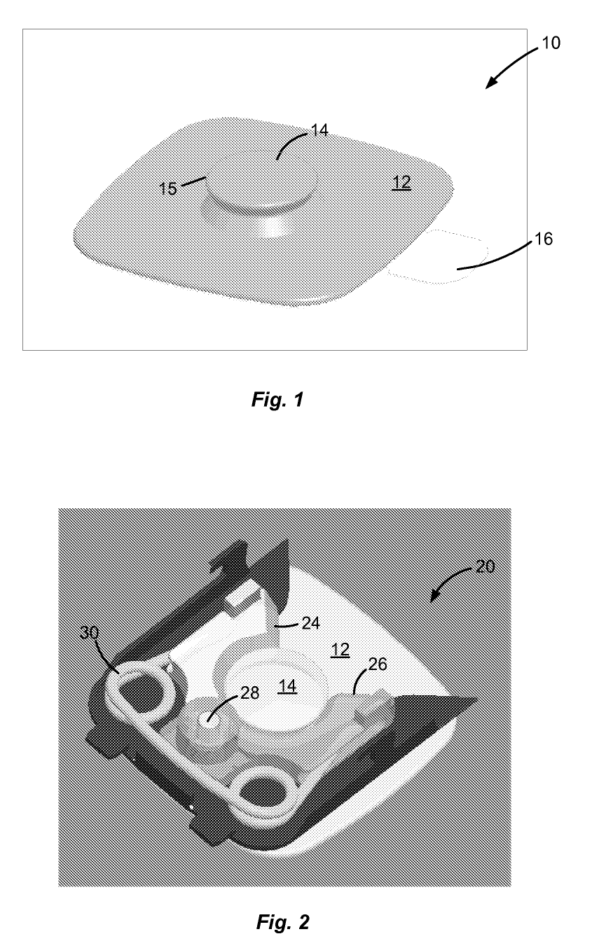

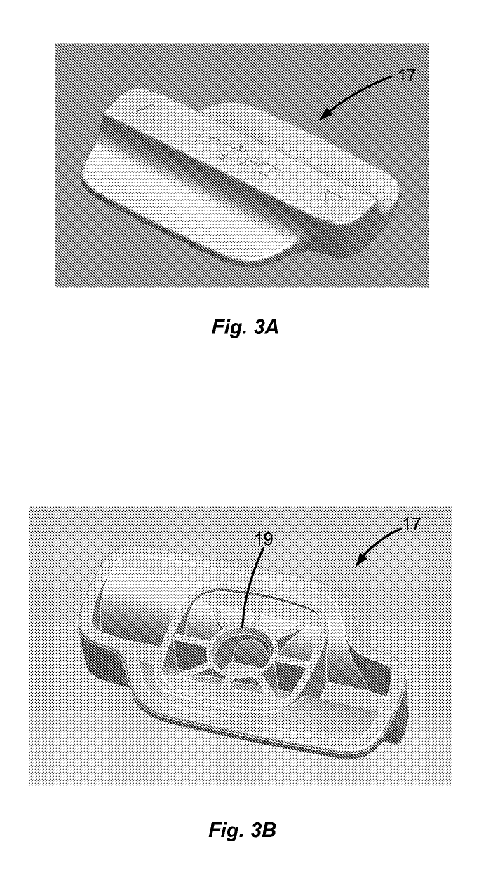

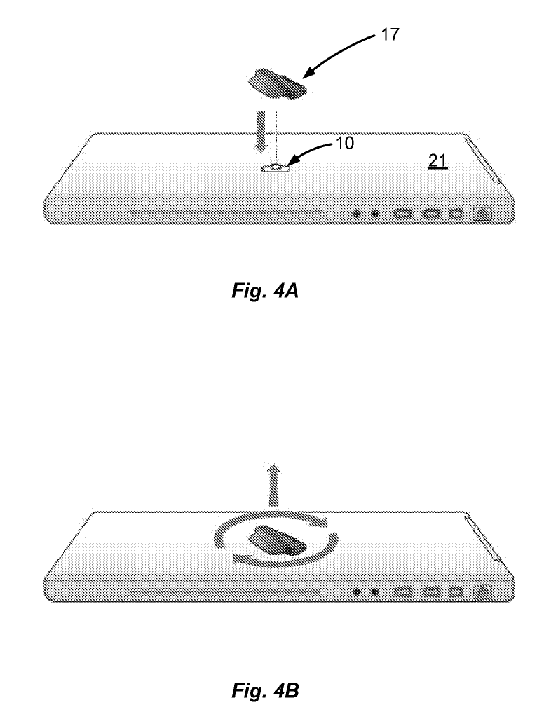

FIG. 1 is a diagram of one embodiment of a docking piece 10 according to embodiment of the invention. The docking piece 10 includes a flat surface 12 with an underside that can attach to a flat surface of a laptop with a removable adhesive or other attaching mechanism. The docking piece includes a mushroom-shaped knob 14 with a lip 15 for engaging an accessory. A small tab 16, when peeled, reveals the adhesive below. A flat tool 17 (see FIGS. 3 and 4 below) can be used to twist the docking piece off a laptop when it is no longer desired to be used.

FIG. 2 is a diagram of a docking element 20 which can be attached to or embedded in an accessory which is to be attached to docking piece 10 of FIG. 1. Docking element 20 is shown engaging the head of mushroom knob 14. A pair of plastic clamps 24 and 26 will engage under the lip 15 of knob 14. The two plastic clamps 24 and 26 pivot around a common axis 28. The clamps are spring biased by a spring 30. In operation, when the accessory is attached to docking piece 10, the clamps 24 and 26 will separate as they are pushed onto knob 14, and then will clamp down around knob 14, under lip 15, under the bias of spring 30, to snap the docking element 20 into place.

Note that the spring-loaded clamping system of FIG. 2 is self-centering. Also, the direction of docking engagement is unlimited, since the docking knob 14 is symmetrical. The clamp spring-loaded clamping action provides tactile feedback of engagement to the user. In order to unlock, the user simply slides the mouse in the opposite direction to unlock it. An advantage of this docking mechanism is that the user can also pull the mouse off vertically without damaging the system.

FIG. 3A shows a top view of a tool 17 for removing docking piece 10, according to one embodiment of the invention. FIG. 3B shows a bottom view, with a circular ring 19 which fits over and clears mushroom-shaped knob 14 of docking piece 10. The tool grips on the 4 sides of the flat piece 12 to grip it for removal. The adhesive tape used to hold docking piece 10 is typical of many adhesives in that it is strong in tension and shear but is weak in torsional shear. Thus, it would be difficult to pry docking piece off, but relatively easy to twist it off, using tool 17 to grip it.

FIGS. 4A and 4B illustrate the use of tool 17 to remove docking piece 10 from a back surface 21 of a laptop screen, according to one embodiment of the invention. The tool is first placed over docking piece 10 as shown in FIG. 4A, then twisted to remove it as shown in FIG. 4B.

### ON/OFF Button

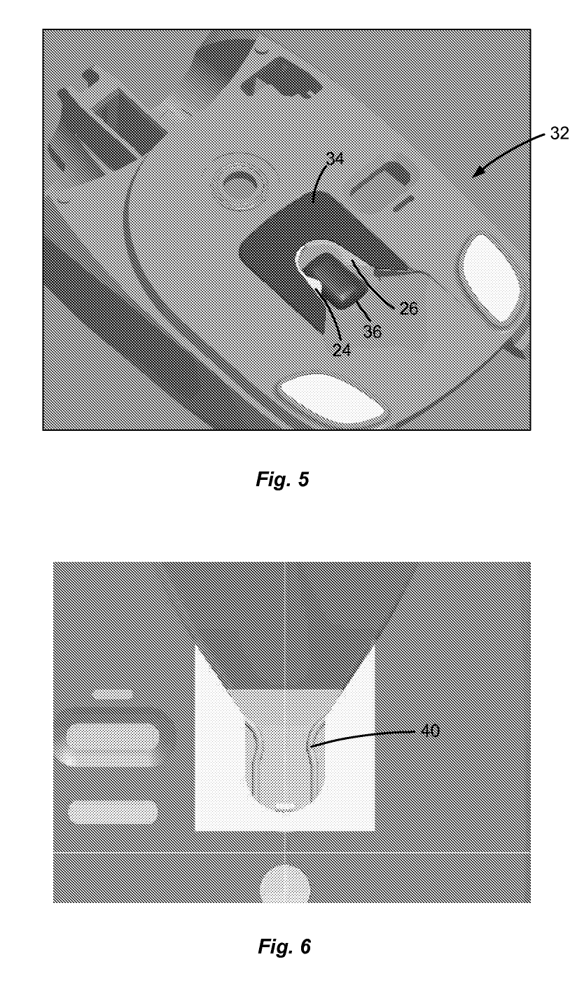

FIG. 5 is a diagram of docking element 20 of FIG. 2 mounted in the underside of a mouse 32. The mechanism is mostly hidden under a cover 34 with clamps 24 and 26 visible under the edges. An on/off button 36 is added. When the docking element of the mouse engages the knob 14 of the docking piece, knob 14 will press button 36, thereby turning off power to the mouse. When the mouse is removed, the knob will release button 36, thereby turning the mouse back on.

### Metal Wire Clamp

FIG. 6 is a diagram of an alternate embodiment of the docking element using a metal wire 40. Wire 40 is shaped to have a narrower gap where it will initially engage knob 14, and a wider gap farther in, thereby allowing the snapping into place of the mouse. This embodiment also allows docking and undocking in any direction, and also allows vertical pull off by the user without damaging the system.

### Vertical Rotating Metal Clamps

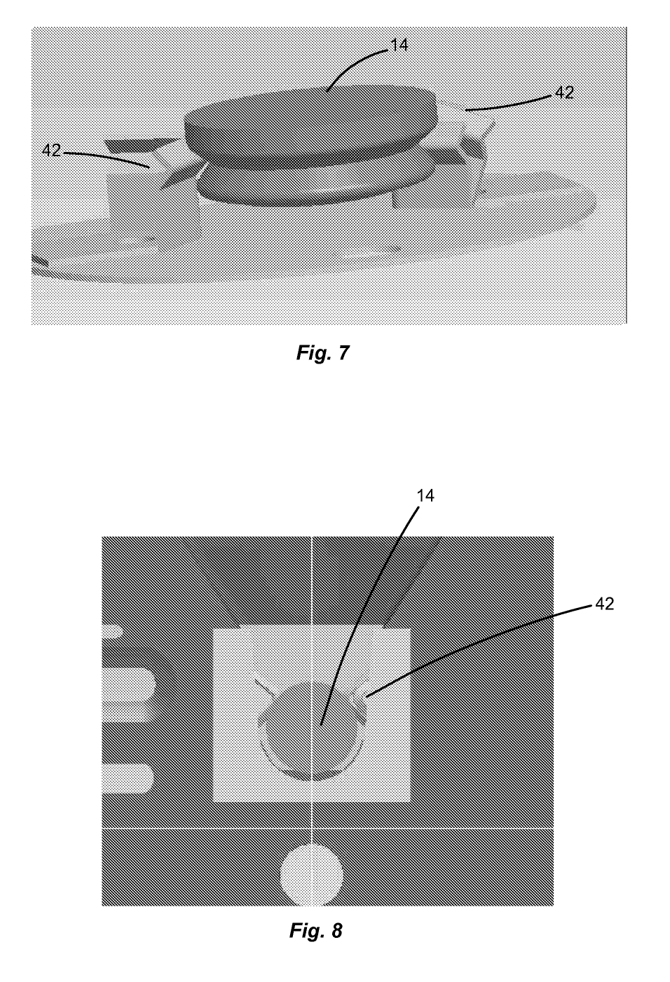

FIG. 7 is a diagram with yet another embodiment for engaging knob 14 with vertical rotating metal clamps 42. FIG. 8 is a top view of the diagram of FIG. 7 showing knob 14 pushed into placed past the midpoint of clamps 42. Like the previous embodiment, this allows docking and undocking from any direction, and also allows vertical pull off by the user. These clamps will twist in the direction of the vertical pull, basically bending backwards as it is pulled off.

### Rubber Clamps

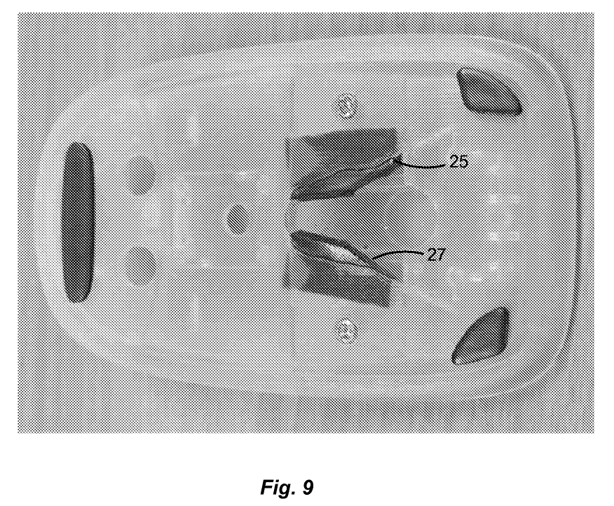

In an alternate embodiment, shown in FIG. 9, clamps such as clamps 24 and 26, could be replaced with rubber pieces 25 and 27. Thus, instead of the clamps being movable and spring loaded, they can be fixed rubber pieces which compress and expand as a docking element is locked onto the knob 14 of the docking piece 10. This embodiment also allows docking and undocking from any direction, and allows vertical pull off. Alternately, knob 14, or the edges of knob 14 of docking piece 10 could be made of rubber, while the clamp structure of docking element 20 could be fixed and solid.

### Press Fit Groove, Metal Ball for Tactile Feedback

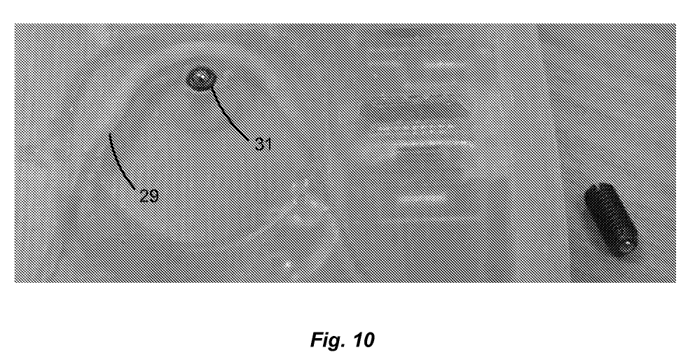

In yet another embodiment as shown in FIG. 10, the docking element simply includes a groove 29 which slides around the head of knob 14 and it engages under the lip 15. The clamping function would be provided by a press fit. In one embodiment, rubber or other resilient materials could be used to provide some compression force for the press fit. In addition, a spring-loaded metal ball 31 can be placed near the end of the slot on the mouse to give tactile feedback when it is fully docked.

### Magnetic Attachment

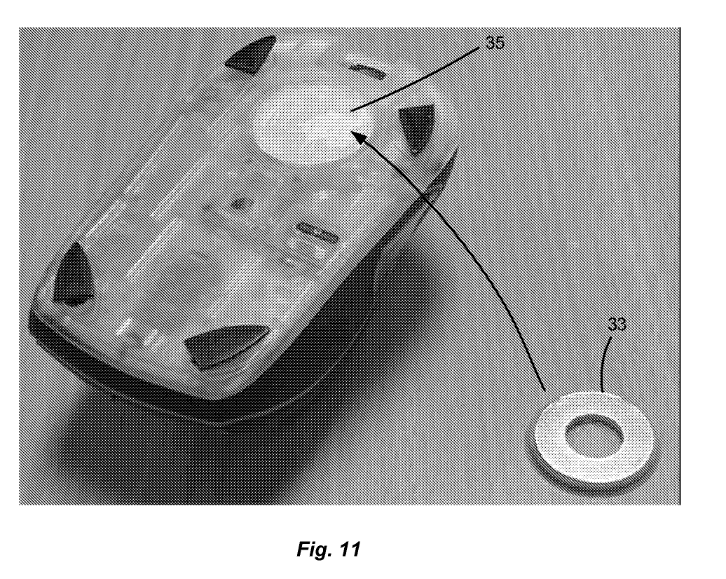

In another embodiment, knob 14 can have other shapes or can be magnetic. FIG. 11 is a diagram of an embodiment with magnetic and metal pieces used for the docking piece and docking element. A metal piece 33 is included in the mouse inside plastic bottom housing 35 to provide a magnetic attachment to the magnet. Alternately, a magnetic piece can be included in the mouse and a metal piece is included on the docking piece. In one embodiment, the magnet is mounted directly on the outside of a mouse, and not covered by the base, so it is visible to the user.

In one embodiment, the magnetic can be an electro magnetic, requiring a button be pressed to provide electricity and activate it. A magnetic on the mouse embodiment could have the magnetic covered by the logo of the company manufacturing it. Alternately, the mouse pad could be magnetic so that they double as magnetics and feed for the mouse. An alternate embodiment, an electro static magnet force could be used. The magnet on the laptop could be a magnetic sticker which is permanently stuck to the laptop case. The sticker can engage a metal part (ferro magnetic) in the mouse.

### CLIPPED EMBODIMENTS

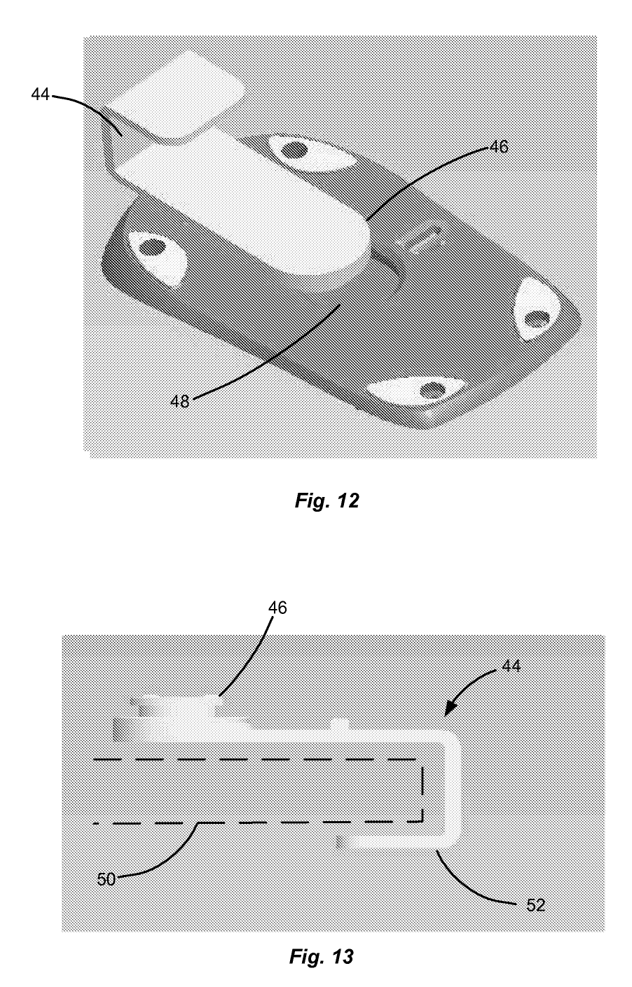

An alternate attachment mechanism is shown in the embodiment of FIG. 12. A clip piece 44 acts as a docking piece by clipping over the edge of the display of a laptop, much like a webcam style clip. Piece 44 includes a rounded portion 46 which engages a slot 48 in the docking element on the bottom of the mouse.

FIG. 13 shows a side view of clip 44 as it would attach to the edge of a computer display 50. Rounded portion 46 includes a lip with a groove for engaging a slot on the bottom of the mouse as shown in FIG. 12. An edge 52 of the clip, which engages a laptop display, can be spring-loaded or it can be a resilient spring material to provide a clamping force. Alternately, clamping can be provided simply by closing the laptop, thus, sandwiching portion 52 between the display and keyboard portions of the laptop.

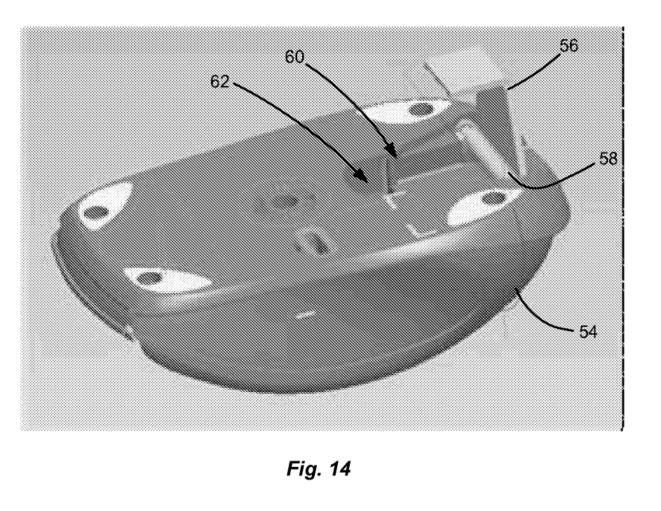

FIG. 14 is a diagram of an embodiment using the spring loaded rotating latch. A mouse 54 includes a latch 56 which rotates about an axle 58. The latch 56 is normally biased downward into a slot 60 where it will not interfere with normal mouse operation. The slot extends into a portion 62 which allows the user to insert a finger and pull the latch outward against the bias of the spring against the axle 58. Clamp 56 can then be placed on the edge of the computer display, or other edge of the computer laptop. Similar to the other latch mechanism described above, it can also rely on the sandwiching effect of the laptop keyboard and display sections to hold it in place.

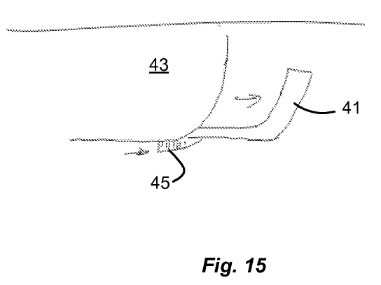

In an alternate embodiment as shown in FIG. 15, instead of rotating out of an enclosure within the mouse, the clamp 41 can slide of out the mouse 43 with the bent end of the clamp being flush with the end of the mouse, such as the rear end of the mouse, in the closed position. The user presses against a knob 45 to move the claim out and in. A spring can bias the clamp to slide into the mouse, thus providing the spring force when it is slid out. The spring force will help clamp against the laptop display. This embodiment allows the clamp to self adjust to the thickness of the screen.

### Adhering Mechanisms

As described above, the docking piece can be attached to the laptop by a reusable adhesive. Alternately, a Velcro® fastener can be used. In another embodiment, a suction cup could be used, or an array of small suction cups. Another embodiment uses synthetic Gecko hair for dry adhesion. (see, e.g.: http://nanolab.me.cmu.edu/projects/Geckohair).

In one embodiment, any one of the adhering mechanisms described above can be used to attach the mouse or other accessory to the docking piece. Thus, the docking piece could have adhesive on the bottom and on its top, with the bottom portion being for attaching to the laptop, and the top portion for attaching to the mouse. Alternately, an adhesive could be used for the bottom and a Velcro® fastener for the top, or any other combination.

In one embodiment, the hook-typed structures described above could include an end portion which engages one of the many slots on a laptop. For example, it could engage the USB slot, PCI slot, video output slot, speaker holes, etc.

It is to be understood that the examples and embodiments described above are for illustrative purposes only and that various modifications or changes in light thereof will be suggested to persons skilled in the art and are to be included within the purview of this application and scope of the appended claims. For example, other shapes for the clamping elements could be used. Alternately, a trackball, joystick, gamepad, webcam, head phone or other peripheral could be attached to the laptop. Therefore, the above description should not be understood as limiting the scope of the invention as defined by the claims.

What is claimed is:

1. A docking system for attaching an accessory to a laptop computer, comprising:
a docking piece attachable to a flat surface of the laptop;
an accessory; and
a docking element attachable to said accessory to engage the docking piece with a restraining force applied.

2. The system of claim 1 wherein said accessory is a computer mouse.

3. The system of claim 1 wherein said docking piece attaches to said laptop computer with an adhering material.

4. The system of claim 1 wherein said docking piece attaches to said laptop computer with a hook that engages one of a display edge and a peripheral slot.

5. The docking system of claim 1 wherein said docking element includes a pair of spring loaded clamps for providing said restraining force.

6. The docking system of claim 1 wherein said docking element includes a resilient material for providing said restraining force.

7. The docking system of claim 1 wherein said docking element includes a magnet for providing said restraining force.

8. The docking system of claim 1 wherein said docking element includes an adhering mechanism for providing said restraining force.

9. The docking system of claim 8 wherein said adhering mechanism comprises a plurality of suction cups.

10. The docking system of claim 8 wherein said adhering mechanism comprises a reusable adhesive.

11. The docking system of claim 8 wherein said adhering mechanism comprises Gecko hair.

12. The docking system of claim 1 wherein said docking element includes a bendable wire for providing said restraining force.

13. The docking system of claim 1 further comprising:
an on/off switch on a portion of said accessory which engages said docking piece; and
an element on said docking piece which engages said on/off switch to turn off power to said accessory when it is docked on said docking piece.

14. The system of claim 1 further comprising:
wherein said docking piece includes a mushroom shaped element; and
wherein said docking element includes
a slot for engaging said mushroom shaped element, and
a resilient piece for applying a clamping force to said mushroom shaped element.

15. The docking system of claim 1 further comprising:
a removal tool having a bottom surface shaped to engage said docking piece, and top surfaces shaped to allow rotating engagement by the fingers of a user.

16. A docking system for attaching an computer mouse to a laptop computer, comprising:
a docking piece attachable to a flat surface of the laptop with an adhering material;
an computer mouse;
a docking element attached to said computer mouse to engage the docking piece with a restraining force applied;
an on/off switch on a portion of said computer mouse which engages said docking piece; and
an element on said docking piece which engages said on/off switch to turn off power to said computer mouse when it is docked on said docking piece.
